(19) United States
(12) Patent Application Publication
(10) Pub. No.: US 2025/0382432 A1
(43) Pub. Date: Dec. 18, 2025

(54) Substrate Processing Method and Substrate Processing Apparatus

(71) Applicant: Tokyo Electron Limited, Tokyo (JP)

(72) Inventor: Tatsuya YAMAGUCHI, Yamanashi (JP)

(21) Appl. No.: 19/223,896

(22) Filed: May 30, 2025

(30) Foreign Application Priority Data
Jun. 14, 2024 (JP) 2024-096630

(51) Int. Cl. C08J 11/16; H01J 37/32; H01L 21/3105

(52) U.S. Cl. CPC C08J 11/16; H01J 37/32449; H01L 21/31058; H01J 2237/338

(57) ABSTRACT

A substrate processing method is provided. The method comprises: (a) providing a substrate having a recess in which a polymer material having a urea bond is embedded by a vapor deposition polymerization reaction of a first monomer and a second monomer; and (b) heating the substrate to a temperature at which the polymer material is thermally decomposed to decompose the polymer material by depolymerization, wherein said (b) includes supplying a processing gas containing hydrogen, oxygen, or a halogen-based gas to decompose and gasify the reactive monomer generated by the depolymerization by active species contained in the plasma of the processing gas.

### CROSS-REFERENCE TO RELATED APPLICATIONS

This application claims priority to Japanese Patent Application No. 2024-096630 filed on Jun. 14, 2024, the entire contents of which are incorporated herein by reference.

### TECHNICAL FIELD

The present disclosure relates to a substrate processing method and a substrate processing apparatus.

### BACKGROUND

For example, U.S. Pat. No. 11,637,037 proposes a method for forming an air gap on a substrate. U.S. Pat. No. 11,637,037 discloses “a method including: (a) providing a semiconductor substrate having an exposed layer of tin oxide, and exposing the semiconductor substrate sequentially to a tin-containing precursor and an oxygen-containing precursor to provide the tin oxide layer; and (b) etching the exposed layer of tin oxide at a temperature of less than about 100° C., wherein the etching includes forming a volatile tin hydride by exposing the semiconductor substrate to plasma produced from a processing gas containing at least about 50% H₂, and the etching is performed without forming a solid product on the semiconductor substrate.”

### SUMMARY

The present disclosure provides a substrate processing method and a substrate processing apparatus capable of improving productivity.

The substrate processing method comprises: (a) providing a substrate having a recess in which a polymer material having a urea bond is embedded by a vapor deposition polymerization reaction of a first monomer and a second monomer; and (b) heating the substrate to a temperature at which the polymer material is thermally decomposed to decompose the polymer material by depolymerization, wherein said (b) includes supplying a processing gas containing hydrogen, oxygen, or a halogen-based gas to decompose and gasify the reactive monomer generated by the depolymerization by active species contained in the plasma of the processing gas.

### BRIEF DESCRIPTION OF THE DRAWINGS

FIG. 1 is a flowchart showing an example of a substrate processing method according to a reference example.

FIG. 2A is a diagram showing an example of substrate processing.

FIG. 2B is a diagram showing an example of substrate processing.

FIG. 2C is a diagram showing an example of substrate processing.

FIG. 2D is a diagram showing an example of substrate processing.

FIG. 2E is a diagram showing an example of substrate processing.

FIG. 3 is a diagram showing an example of the results of a test on cleaning.

FIG. 4 is a diagram showing an example of the results of a test on plasma treatment.

FIG. 5 is a flowchart showing an example of a substrate processing method according to an embodiment.

FIG. 6 is a diagram showing deposition polymerization, depolymerization, and decomposition and gasification of a polymer having a urea bond.

FIG. 7 is a diagram showing an example of a substrate processing apparatus.

### DETAILED DESCRIPTION

Hereinafter, embodiments of a substrate processing method and a substrate processing apparatus of the present disclosure will be described in detail with reference to the accompanying drawings. Further, the embodiments are not intended to limit the substrate processing method and the substrate processing apparatus of the present disclosure. The following embodiments may be combined as appropriate, provided that such combinations do not conflict with the configurations or processing steps disclosed herein.

Further, the drawings referred to below are schematic for convenience of description. Therefore, the details thereof may be omitted, and the dimensional ratios in the drawings do not necessarily indicate the actual ratios.

### (Substrate Processing Method According to Reference Example)

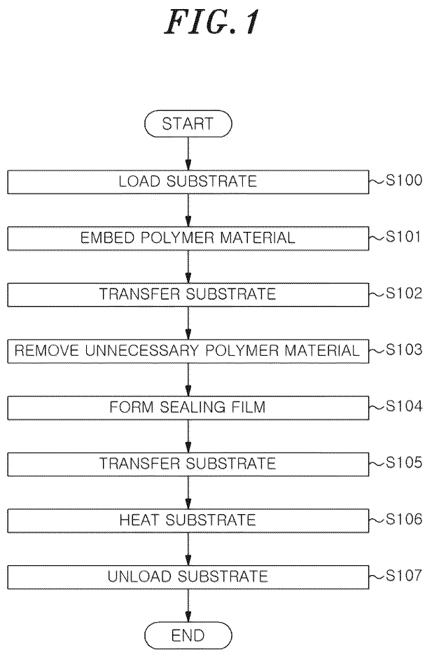

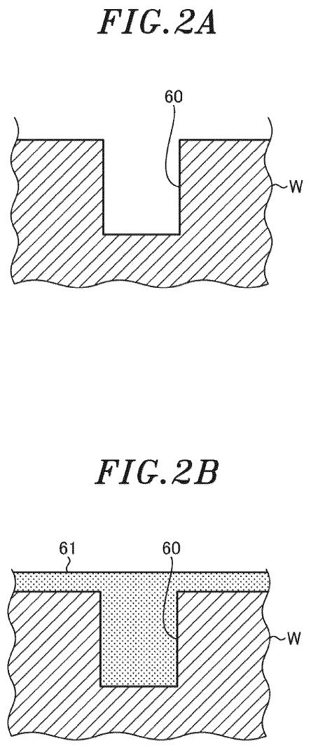

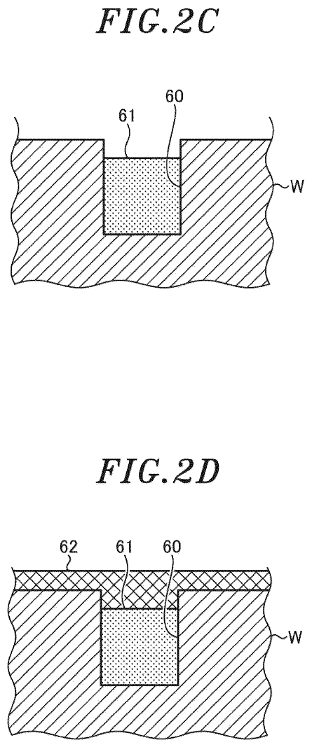

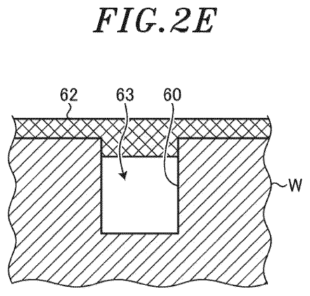

First, an example of a substrate processing method according to a reference example will be described with reference to FIG. 1 and FIGS. 2A to 2E. FIG. 1 is a flowchart showing an example of a substrate processing method according to the reference example. FIGS. 2A to 2E are diagrams showing an example of substrate processing.

In the substrate processing method according to the reference example, a substrate W is loaded into a chamber of a substrate processing apparatus (step S100). In step S100, as shown in FIG. 2A, for example, the substrate W with a recess 60 is loaded into the chamber of the substrate processing apparatus. For example, the recess 60 may be formed in a metal film such as ruthenium or the like.

Next, a polymer material is embedded in the recess 60 (step S101). The polymer material is thermally decomposed in a subsequent process, and serves as a sacrificial film that is removed from the recess 60 to form an air gap in the recess 60. As a result, the polymer material 61 is embedded in the recess 60, as shown in FIG. 2B, for example.

Next, the substrate W is unloaded from the chamber of the substrate processing apparatus that has performed the process of step S101, and is transferred into the chamber of the substrate processing apparatus that will perform the process of subsequent step S103 (step S102).

Next, the unnecessary polymer material 61 on the substrate W is removed (step S103). In step S103, plasma is generated from a processing gas in the chamber. The processing gas is, for example, a mixture of hydrogen gas and nitrogen gas. The unnecessary polymer material 61 formed around the recess 60 is removed by the generated plasma, for example, as shown in FIG. 2C.

Next, a sealing film is formed on the recess 60 in which the polymer material 61 is embedded (step S104). In step S104, plasma is generated from a processing gas such as organic aminosilane or the like in the chamber. Then, a sealing film 62 that covers the recess 60 in which the polymer material 61 is embedded is formed by the generated plasma as shown in FIG. 2D, for example.

Next, the substrate W is unloaded from the chamber of the substrate processing apparatus that has performed the process of step S104, and is transferred into the chamber of the substrate processing apparatus that will perform the process of subsequent step S106 (step S105).

Next, the substrate W is heated (step S106). In step S106, the substrate W is heated to a temperature of less than 400° C., for example. Accordingly, the polymer material 61 is thermally decomposed, and is desorbed through the sealing film 62. As a result, as shown in FIG. 2E, for example, the polymer material 61 in the recess 60 disappears, thereby forming an air gap 63 in the recess 60. The air gap 63 is a space in the recess 60, and is defined by the recess 60 and the sealing film 62.

Next, the substrate W is unloaded from the substrate processing apparatus that has performed the process of step S106 (step S107). Accordingly, the substrate processing method according to the reference example is completed.

### (Repolymerized Product)

In the thermal decomposition of a polymer material including two types of monomers, radical components are generated by bond dissociation, so that carbonized components may become residues. For example, in the process of step S106, the polymer material 61 is released from the substrate W in the form of thermal decomposition referred to as depolymerization, and reverts to a monomer. Then, the monomer of the desorbed component (desorbed gas) thus generated is repolymerized in the chamber, thereby forming a repolymerized product. Hereinafter, the monomer generated by depolymerization is also referred to as “reactive monomer.”

The repolymerized product may adhere in the form of fine powder to a chamber wall, a stage, or the like, thereby serving as a source of particle contamination. Thus, a method for heating the entire chamber to 250° C. or higher at which depolymerization occurs may be considered in order to prevent the repolymerization of the reactive monomer and prevent the generation of particles. Accordingly, the repolymerized product can be thermally decomposed. However, due to constraints such as the inability to install heaters at the bottom of the chamber, it is practically difficult to heat the entire chamber to 250° C. or higher.

On the other hand, dry cleaning may be periodically performed to remove the repolymerized product adhered to the inner portion of the chamber. Since, however, dry cleaning is performed in a state where the chamber is opened to the atmosphere, the maintenance time is long, which results in deterioration of productivity.

### (Removal of Repolymerization: Test Results)

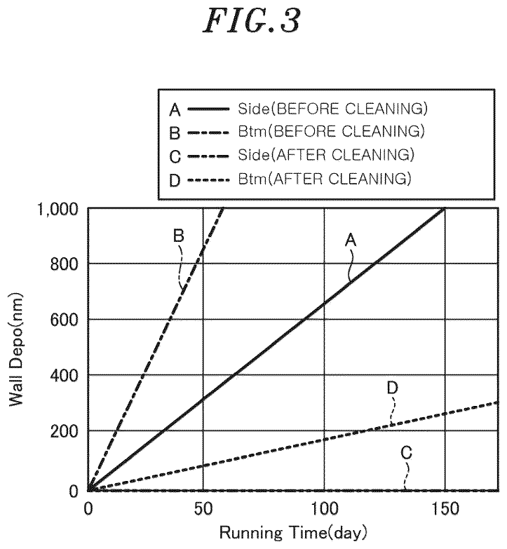

In order to remove the repolymerized product, in Test 1, thermal cleaning was periodically performed during the process of step S106. Specifically, in Test 1, the temperature of the stage on which the substrate W was placed was controlled to 400° C., and the residue of the repolymerized product was removed by the thermal cleaning. FIG. 3 shows an example of the results of the test on cleaning.

In FIG. 3, the horizontal axis represents the operation days of the device, and the vertical axis represents the thickness of the repolymerized product adhered to the chamber wall. A line (A) indicates the thickness of the repolymerized product on the chamber side surface (Side) before cleaning. A line (B) indicates the thickness of the repolymerized product on the chamber bottom surface (Btm) before cleaning. A line (C) indicates the thickness of the repolymerized product on the chamber side surface after cleaning. A line (D) indicates the thickness of the repolymerized product on the chamber bottom surface after cleaning.

The thickness of the repolymerized product on the chamber side surface after cleaning, which is indicated by the line C, was substantially zero. In other words, the repolymerized product on the chamber side surface was substantially completely removed by the thermal cleaning. However, the repolymerized product on the chamber bottom surface after cleaning, which is indicated by the line D, gradually increased, and became too thick to ignore the possibility of particle generation after 100 to 150 days of operation.

The repolymerized product on the chamber bottom surface becomes thick because the temperature is lower on the chamber bottom surface than on the chamber side surface, which causes more repolymerized product to be adhered to the chamber bottom surface than to the chamber side surface. In addition, the chamber side surface is close to a plasma generation space, so that the cleaning rate is higher due to the increase in the temperature caused by the heat input of the plasma during the cleaning. On the other hand, the chamber bottom surface is far from the plasma generation space, and the increase in the temperature during the cleaning is small, so that the cleaning rate is lower compared to that on the chamber side surface. As a result, as the operation days of the device increases, the repolymerized product is gradually accumulated on the chamber bottom surface, and reaches a thickness at which the possibility of particle generation cannot be ignored. From the results of Test 1, in order to prevent the generation of particles, it is necessary to perform not only thermal cleaning but also dry cleaning after a certain number of operation days of the device. However, in this case, the productivity is reduced due to the dry cleaning.

### (Removal of Repolymerized Product: Test Results)

Therefore, in order to remove the repolymerized product without requiring dry cleaning, plasma treatment was performed in Test 2. Specifically, in Test 2, when the process of step S106 was performed, the substrate W was heated to 400° C. under the following processing conditions, and the plasma treatment was performed by exposing the substrate W to the plasma of the processing gas supplied into the chamber. The temperature of the substrate W may be the temperature of the stage on which the substrate W is placed.
Chamber pressure: 2.0 Torr (266.6 Pa)
Processing gas: H₂/Ar=1000 sccm/100 sccm
RF power: 200 W
Temperature of substrate W: 400° C.
Plasma: applied

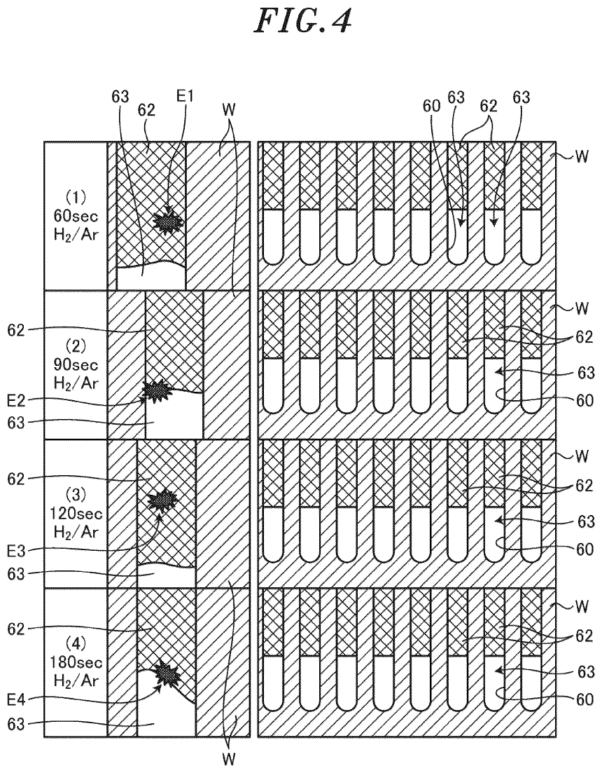

FIG. 4 shows an example of the results of a test on plasma treatment. FIGS. 4(1) to 4(4) illustrate cross-sectional views of substrate W having an air gap 63 and sealing film 62, after the polymer material 61 was removed, when the processing time in step S106 was set to 60, 90, 120, and 180 seconds, respectively. The images on the left side are enlarged images of a part of the images on the right side. As shown in (1) to (4) of FIG. 4, regions E1 to E4 of the sealing film 62 were eroded by the plasma. Further, as the processing time became longer, the removal amount of the sealing film 62 increased and the damages to the sealing film 62 increased.

In addition, in another test, the process of step S106 was performed while supplying argon gas at 1000 sccm into the chamber. The processing conditions other than the processing gas were the same as those in Test 2. As a result of this test, in the case of using plasma generated from argon gas only in the process of step S106, when the processing time was extended, the amount of repolymerized product decreased, but the residue of the repolymerized product remained on the substrate W.

### (Substrate Processing Method According to Embodiment)

Based on the results of the above tests, in the substrate processing method according to an embodiment of the present disclosure, when the polymer material 61 is thermally decomposed, the reactive monomer desorbed from the substrate W by depolymerization is decomposed and gasified. Further, in the substrate processing method, the reactive monomer is decomposed and gasified using active species contained in the plasma without damaging the metal wiring or the sealing film 62 on the substrate W. More specifically, the flow rate of the hydrogen gas is controlled such that the active species contained in the hydrogen gas plasma are consumed in the decomposition and gasification of the reactive monomer without reaching the substrate W. Due to the decomposition and gasification of the reactive monomer, the generation of repolymerized product is suppressed, and the periodic dry cleaning is not required, thereby improving productivity. In addition, due to the decomposition and gasification of the reactive monomer, the possibility of particle generation is reduced, and the yield increases. In addition, damage to the substrate W is reduced.

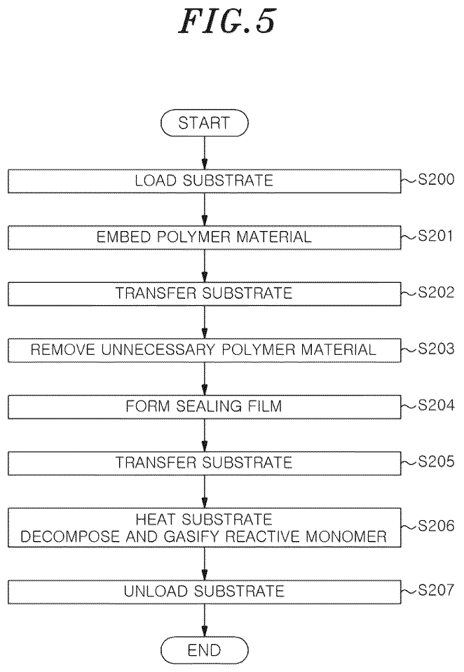

A substrate processing method according to an embodiment of the present disclosure will be described with reference to FIG. 5. FIG. 5 is a flowchart showing an example of a substrate processing method according to an embodiment. The substrate processing method according to an embodiment is performed by the substrate processing apparatus and controlled by the controller for controlling the substrate processing apparatus. For example, the process of step S203 is performed by a substrate processing apparatus 30 shown in FIG. 7, which will be described later, and controlled by the controller 40. However, the substrate processing apparatus for performing the substrate processing method and the controller for controlling the substrate processing method are not limited to the device configuration shown in FIG. 7.

The controller loads the substrate W with the recess 60 into the chamber of the substrate processing apparatus (step S200). In step S200, as shown in FIG. 2A, for example, the substrate W with the recess 60 is loaded into the chamber of the substrate processing apparatus.

Next, the controller fills the recess 60 with a polymer material having a urea bond by the vapor deposition polymerization reaction of a first monomer and a second monomer (step S201). In step S201, the first monomer and the second monomer are supplied into the chamber. The first monomer and the second monomer cause the vapor deposition polymerization reaction, so that the polymer material is embedded in the recess 60 of the substrate W. In the present embodiment, the first monomer may be, for example, isocyanate, and the second monomer may be, for example, polyamine. The polymer material having a urea bond may be polyurea. As a result, as shown in FIG. 2B, for example, the polymer material 61 is embedded in the recess 60.

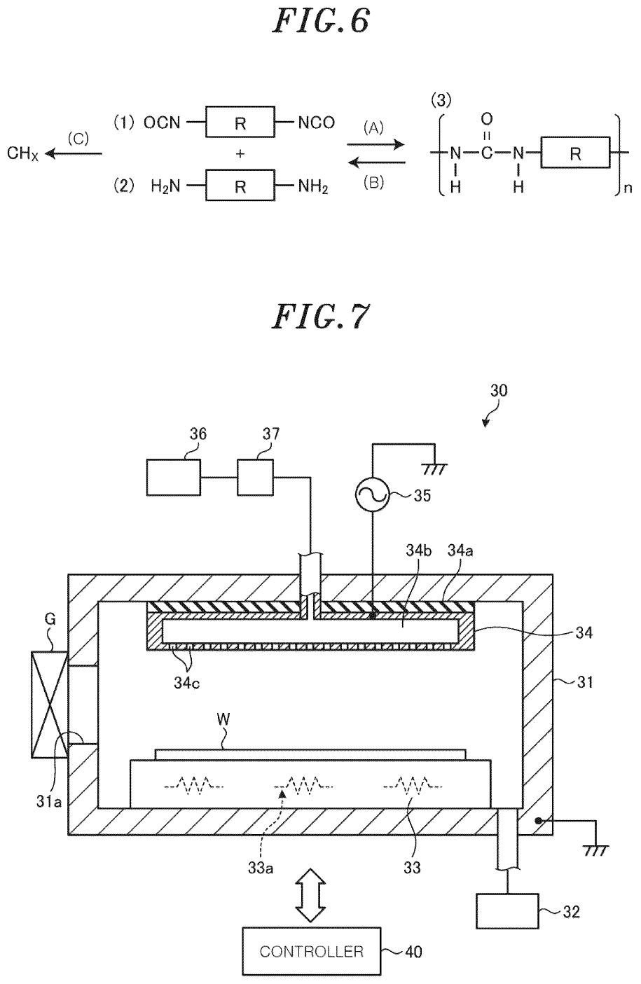

FIG. 6 is a diagram showing deposition polymerization, depolymerization, and decomposition and gasification of a polymer having a urea bond. For example, (1) of FIG. 6 shows isocyanate. Further, (2) of FIG. 6 shows polyamine. The isocyanate and the polyamine form a polymer material containing polyurea shown in (3) of FIG. 6 by the deposition polymerization reaction (see (a) of FIG. 6). The isocyanate is an example of the first monomer. The polyamine is an example of the second monomer. The polymer material containing polyurea is an example of a polymer material having a urea bond. Further, “R” connected to the urea bond shown in (3) of FIG. 6 is an alkyl group (linear alkyl group or cyclic alkyl group) or an aryl group, for example, and n is an integer of 2 or more. Similarly, “R” in (1) and (2) of FIG. 6 is an alkyl group or an aryl group.

The isocyanate may be, for example, an alicyclic compound, an aliphatic compound, an aromatic compound, or the like. The alicyclic compound may be, for example, 1,3-bis(isocyanatomethyl)cyclohexane (H6XDI). The aliphatic compound may be, for example, hexamethylene diisocyanate. Polyamine is a general term for linear aliphatic hydrocarbons in which three or more amino groups are bonded.

In step S201, the polymer material 61 is embedded in the recess 60 of the substrate W under the following processing conditions, for example.
Chamber pressure: 0.5 Torr to 20 Torr (66.7 Pa to 2666 Pa)
Flow rate of isocyanate vapor: 1 sccm to 20 sccm
Flow rate of polyamine vapor: 1 sccm to 20 sccm
Temperature of substrate W: 40° C. to 150° C.

Then, the controller unloads the substrate W from the chamber of the substrate processing apparatus that has performed the process of step S201, and transfers the substrate W into the chamber of the substrate processing apparatus that will perform the process of subsequent step S203 (step S202).

Then, the controller removes the unnecessary polymer material 61 on the substrate W (step S203). In step S203, plasma is generated from the processing gas in the chamber 31. The processing gas is a mixed gas of hydrogen gas and nitrogen gas. Further, the unnecessary polymer material 61 formed around the recess 60 is removed by the generated plasma as shown in FIG. 2C, for example.

In step S203, the unnecessary polymer material 61 is removed under the following processing conditions, for example. The temperature of the substrate W may be the temperature of the stage on which the substrate W is placed.
Chamber pressure: 0.05 Torr to 1.0 Torr (6.67 Pa to 133 Pa)
Processing gas: H₂/N2=100 sccm to 300 sccm/100 sccm to 300 sccm
RF power: 100 W to 400 W
Temperature of substrate W: 40° C. to 200° C.

Next, the controller forms a sealing film on the recess 60 in which the polymer material 61 is embedded (step S204). In step S204, plasma is generated from a processing gas such as organic aminosilane in the chamber. Then, the sealing film 62 that covers the recess 60 in which the polymer material 61 is embedded is formed by the generated plasma, as shown in FIG. 2D. The sealing film 62 is, e.g., a silicon oxide film. Further, the sealing film 62 may be another silicon-containing film such as a silicon nitride film or the like.

In step S204, the sealing film 62 is formed under the following processing conditions, for example. Further, the temperature of the substrate W may be the temperature of the stage on which the substrate W is placed.
Chamber pressure: 0.1 Torr to 10 Torr (13.3 Pa to 1333 Pa)
Processing gas: organic aminosilane=10 sccm to 50 sccm
RF power: 50 W to 200 W
Temperature of substrate W: 20° C. to 200° C.

Next, the controller 40 provides the substrate W having the recess 60 filled with the polymer material 61 and the sealing film 62 (step S205). Step S205 is an example of a process (a). In step S205, the substrate W is unloaded from the chamber of the substrate processing apparatus that has performed the process of step S204, and is transferred into the chamber 31 of the substrate processing apparatus 30 that will perform the process of subsequent step S206.

Next, the controller 40 heats the substrate W (step S206). Further, the controller 40 decomposes and gasifies the reactive monomer desorbed from the substrate W by depolymerization during the process using active species (radicals) contained in the hydrogen gas plasma (step S206). In step S206, the substrate W is heated under the following processing conditions, for example, and the reactive monomer is decomposed and gasified. Further, the temperature of the substrate W may be the temperature of the stage 33 on which the substrate W is placed.
Chamber pressure: 2.0 Torr to 10 Torr (266.6 Pa to 133.3 Pa)
Processing gas: H₂/Ar=50 sccm to 100 sccm/1000 sccm to 5000 sccm
RF power: 50 W to 200 W
Temperature of substrate W: 200° C. to 500° C.

In step S206, the controller 40 heats the substrate W to a temperature at which the polymer material 61 is thermally decomposed. For example, the controller 40 heats the substrate W to a temperature of 200° C. to 500° C. As a result, the controller 40 decomposes the polymer material 61 by depolymerization and desorbs the polymer material 61 through the sealing film 62. As a result, as shown in FIG. 2E, for example, the polymer material 61 in the recess 60 disappears, thereby forming the air gap 63 between the sealing film 62 and the recess 60.

Further, in step S206, the controller 40 generates plasma from hydrogen gas and argon gas supplied to the chamber 31, and decomposes and gasifies the reactive monomer generated by depolymerization by the active species contained in the plasma of the hydrogen gas. Accordingly, the generation of the repolymerized product due to the repolymerization of the reactive monomer is suppressed.

In step S206, the controller 40 supplies a mixed gas containing hydrogen gas and argon gas as a processing gas. Argon gas is an example of a rare gas. However, the controller 40 may supply a processing gas containing hydrogen, oxygen, or a halogen-based gas. The controller 40 may supply a processing gas containing hydrogen, oxygen or a halogen-based gas, and a rare gas. The controller 40 controls the reactive monomer generated by depolymerization to be decomposed and gasified by the active species contained in the plasma of hydrogen, oxygen or a halogen-based gas.

As shown in FIG. 6, when the polymer material 61 in (3) of FIG. 6 is thermally decomposed, the polymer material 61 is desorbed from the substrate W by the depolymerization reaction (see (b) of FIG. 6). The reactive monomer, which is the desorbed gas generated by depolymerization, is a carbon-based molecule, and can be decomposed and gasified by the active species contained in the plasma of the hydrogen gas. Hereinafter, the decomposition and gasification of the reactive monomer is also referred to as the deactivation of the reactive monomer. CHₓ gas is generated by the decomposition and gasification of the reactive monomer (see (c) of FIG. 6). As a result, the desorbed gas of the reactive monomer that occurs during the process of step S206 is deactivated by the active species of the plasma of the hydrogen gas, and can be prevented from being repolymerized. Accordingly, the repolymerization of the reactive monomer due to the vapor deposition polymerization reaction shown in (a) of FIG. 6 is suppressed. As a result, the repolymerized product is less likely to be reattached to the wall of the chamber 31. Hence, the periodic dry cleaning becomes unnecessary, and the productivity is improved. Further, the generation of the repolymerized product is suppressed, so that the possibility of particle generation can be reduced and the decrease in the yield can be prevented.

In addition, in step S206, the controller 40 controls the flow rate of hydrogen gas such that the active species contained in the plasma of the hydrogen gas are consumed in the decomposition and gasification of the reactive monomer without reaching the substrate W. In other words, the controller 40 controls the flow rate of the hydrogen gas such that all the active species in the plasma of the hydrogen gas are used to inactivate the reactive monomer before they reach the substrate W. Similarly, also in the case of supplying oxygen gas or a halogen-based gas, the controller 40 controls the flow rate of the oxygen gas or the halogen-based gas such that active species contained in the plasma of the oxygen gas or the halogen-based gas are consumed in the decomposition and gasification of the reactive monomer without reaching the substrate W.

For example, the controller 40 may control the flow rate of the gas to less than 10 times the amount of carbon contained in the reactive monomer.

In the case where the inventors performed a test and removed the polymer material 61 having a thickness of 60 nm by thermal decomposition, the amount of carbon contained in the reactive monomer generated by depolymerization was 5.7 cc (5.7 ml). Therefore, in order to decompose and gasify the reactive monomer generated at the time of removing the polymer material 61 having a thickness of 60 nm, it is preferable to generate the minimum amount of activated species required to break the C—C bond of 5.7 cc of carbon contained in the reactive monomer. As a result, the activated species are used to break the C—C bond of 5.7 cc of carbon without reaching the substrate W, so that damages to the substrate W are eliminated.

In order to break the C—C bond of carbon contained in the reactive monomer, one activated hydrogen species is required for one carbon. Further, it is considered that about 10% of the plasma of the hydrogen gas becomes active species. Therefore, in the case of removing the polymer material 61 having a thickness of 60 nm, the controller 40 controls hydrogen gas to be supplied at a flow rate of about 50 sccm, which is about 10 times 5.7 cc, into the chamber 31. As a result, the controller 40 can break the C—C bond of 5.7 cc of carbon with about 10% of the activated species contained in the plasma of the hydrogen gas to generate CHₓ gas. Further, by controlling the flow rate of the hydrogen gas, the activated species are consumed before they reach the substrate W and, thus, damages to the substrate W are reduced. However, the controller 40 may control the flow rate of the gas to be less than 100 times the carbon contained in the reactive monomer. In this case, most of the activated species are consumed before they reach the substrate W, so that damages to the substrate W are reduced.

Next, the controller 40 unloads the substrate W from the substrate processing apparatus where the process of step S206 has been performed (step S207). Accordingly, the substrate processing method according to one embodiment is completed.

### (Example of Substrate Processing Apparatus)

An example of the substrate processing apparatus that performs the process of step S206 will be described with reference to FIG. 7. FIG. 7 is a diagram showing an example of the substrate processing apparatus. The substrate processing apparatus that performs the process of step S206 may be a capacitively coupled plasma processing apparatus as shown in FIG. 7, or an inductively coupled plasma processing apparatus. Further, the substrate processing apparatus may be a single-wafer type substrate processing apparatus for processing substrates W one by one or a batch type substrate processing apparatus for processing a plurality of substrates W simultaneously.

The substrate processing apparatus 30 includes a chamber 31 and a controller 40. The chamber 31 is made of a conductive material, and is grounded. The chamber 31 has a sidewall with a side surface (Side) and a bottom wall with a bottom surface (Btm). An exhaust mechanism 32 is connected to the chamber 31. The exhaust mechanism 32 has a pressure control valve. The exhaust mechanism 32 exhausts a gas from the chamber 31, and controls the pressure control valve such that the pressure in the chamber 31 becomes a predetermined pressure.

A stage 33 on which the substrate W is placed is provided in the chamber 31. The substrate W is loaded into and unloaded from the chamber 31 via a loading/unloading port 31a formed in the sidewall of the chamber 31, and is placed on the stage 33. When the substrate W is transferred, the loading/unloading port 31a is opened and closed by a gate valve G. A heater 33a for heating the substrate W is provided in the stage 33. Further, the stage 33 is electrically connected to the bottom wall of the chamber 31, and functions as an anode electrode. A shower head 34 is provided above the stage 33 to face the upper surface of the stage 33. The shower head 34 is made of a conductive material, and is supported at the upper part of the chamber 31 via an insulating member 34a. A power source 35 for supplying a high-frequency power for plasma generation is connected to the shower head 34. The shower head 34 functions as a cathode electrode for the stage 33.

A gas supply source 36 supplies a processing gas. A flow rate controller 37 controls the flow rate of the processing gas supplied from the gas supply source 36, and the processing gas of which flow rate is controlled is supplied into the diffusion space 34b of the shower head 34. The processing gas supplied into the diffusion space 34b is diffused in the diffusion space 34b, and is supplied in a shower-like manner into the chamber 31 from a plurality of injection ports 34c formed at the bottom surface of the diffusion space 34b. In the example of FIG. 3, one gas supply source 36 and one flow rate controller 37 are illustrated. However, in actual cases, a set of the gas supply source 36 and the flow rate controller 37 is provided for each type of gas to be used.

The processing gas supplied into the chamber 31 through the shower head 34 is turned into plasma by the high-frequency power supplied from the power supply 35 to the chamber 31. Then, the reactive monomer generated during the removal of the polymer material 61 is decomposed and gasified by the active species contained in the plasma.

The substrate processing apparatus 30 may perform the processes of steps S206 and S204 in the same chamber 31. In this case, the substrate transfer process of step S205 may be omitted.

The controller 40 processes computer-executable instructions that cause the substrate processing apparatus 30 to perform various processes included in the substrate processing method described in the present disclosure. The controller 40 may be configured to control individual components of the substrate processing apparatus 30 to perform various processes described herein. In one embodiment, the controller 40 may be partially or entirely included in the substrate processing apparatus 30. The controller 40 may include a processing part, a storage part, and a communication interface. The controller 40 is realized by, for example, a computer. The processing part reads a program from the storage part, and executes the read program. Accordingly, various control operations can be performed. The program may be stored in the storage part in advance, or may be acquired via a medium when necessary. The acquired program is stored in the storage part, and is read from the storage part and executed by the processing part. The medium may be various computer-readable storage media, or may be a communication line connected to the communication interface. The processing part may be a central processing unit (CPU). The storage part may include a random access memory (RAM), a read only memory (ROM), a hard disk drive (HDD), a solid state drive (SSD), or a combination thereof. The communication interface communicates with the substrate processing apparatus 30 via a communication line such as a local area network (LAN).

The embodiments of the present embodiment have been described. As described above, the substrate processing method according to the embodiment includes steps (a) and (b). In (a), the substrate W having the recess 60 filled with the polymer material 61 having a urea bond by the vapor deposition polymerization reaction of the first monomer and the second monomer is provided. In (b), the substrate is heated to a temperature at which the polymer material 61 is thermally decomposed, so that the polymer material 61 is decomposed by depolymerization, and the air gap 63 is formed in the recess 60 (see FIG. 2E). Further, in (b), the processing gas containing hydrogen, oxygen, or a halogen-based gas is supplied, so that the reactive monomer generated by depolymerization is decomposed and gasified by the active species contained in the plasma of the gas (see (c) of FIG. 6).

### Effect

In the substrate processing method and substrate processing apparatus according to one embodiment, in the case of forming an air gap, the substrate W is heated to a temperature at which the polymer material 61 is thermally decomposed. As a result, the polymer material 61 is thermally decomposed by depolymerization, and the polymer material 61 is desorbed through the sealing film 62, thereby forming the air gap 63 between the sealing film 62 and the recess 60.

In addition, reactive monomer generated by depolymerization is decomposed and gasified by active species contained in the hydrogen gas plasma. In other words, the reactive monomer is gasified by breaking the C—C bond contained in the reactive monomer by the active species contained in the hydrogen gas plasma. Accordingly, in the substrate processing apparatus, it is possible to suppress adhesion of the repolymerized product due to the repolymerization of the reactive monomer. As a result, in the substrate processing apparatus, periodic dry cleaning is not required, and the productivity can be improved. Further, in the substrate processing apparatus, the desorbed gas of the reactive monomer, which is a source of particle generation, is decomposed and gasified to reduce repolymerization of the reactive monomer, reduce the possibility of particle generation, and prevent a decrease in the yield.

Further, the substrate processing apparatus controls the flow rate of hydrogen, oxygen, or a halogen-based gas such that the active species contained in the plasma of the gas is used to deactivate the reactive monomer without reaching the substrate W. As a result, the substrate processing apparatus can prevent the active species from reaching the substrate W and damaging the substrate W.

Further, the embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

In the embodiment, the first monomer is, for example, isocyanate, and the second monomer is, for example, polyamine. The isocyanate gas and the polyamine gas are mixed in the chamber 31 to form polyurea having a urea bond in the recess of the substrate W supported by the stage 33.

However, the present disclosure is not limited thereto, and the second monomer may be, for example, an amine. Further, a linear polyurea can be generated by using diisocyanate as the first monomer and diamine (for example, primary amine) as the second monomer. The combination of diisocyanate and diamine is, for example, the combination of 4,4′-diphenylmethane diisocyanate (MDI) and 1,12-diaminododecane (DAD). The combination of diisocyanate and diamine is, for example, the combination of 1,3-bis(isocyanatomethyl)cyclohexane (H6XDI) and 1,12-diaminododecane (DAD). The combination of diisocyanate and diamine is, for example, the combination of 1,3-bis(isocyanatomethyl)cyclohexane (H6XDI) and 1,3-bis(aminomethyl)cyclohexane (H6XDA). The combination of diisocyanate and diamine is, for example, the combination of 1,3-bis(isocyanatomethyl)cyclohexane (H6XDI) and hexamethylenediamine (HMDA). The combination of diisocyanate and diamine is, for example, the combination of m-xylylenediisocyanate (XDI) and m-xylylenediamine (XDA). The combination of diisocyanate and diamine is, for example, the combination of m-xylylene diisocyanate (XDI) and benzylamine (BA).

For example, crosslinkable polyurea can be generated by using diisocyanate as the first monomer and triamine (for example, primary amine) or tetraamine (for example, secondary amine) as the second monomer. Further, a trimer having a urea bond can be generated by using monoisocyanate as the first monomer and diamine (for example, primary amine) as the second monomer. Further, a dimer having a urea bond can be generated by using monoisocyanate as the first monomer and monoamine (for example, primary amine) as the second monomer.

Further, the following appendices are disclosed with respect to the above embodiments.

### APPENDIX 1

A substrate processing method comprising:
(a) providing a substrate having a recess in which a polymer material having a urea bond is embedded by a vapor deposition polymerization reaction of a first monomer and a second monomer; and
(b) heating the substrate to a temperature at which the polymer material is thermally decomposed to decompose the polymer material by depolymerization,
wherein said (b) includes supplying a processing gas containing hydrogen, oxygen, or a halogen-based gas to decompose and gasify the reactive monomer generated by the depolymerization by active species contained in the plasma of the processing gas.

### APPENDIX 2

The substrate processing method of appendix 1, wherein said (b) includes controlling the flow rate of the processing gas such that the active species are consumed in the decomposition and gasification of the reactive monomer without reaching the substrate.

### APPENDIX 3

The substrate processing method of appendix 1 or 2, wherein in said (b), the flow rate of the processing gas is controlled to less than 100 times the amount of carbon contained in the reactive monomer.

### APPENDIX 4

The substrate processing method of any one of appendices 1 to 3, wherein in said (b), the flow rate of the processing gas is controlled to less than 10 times the amount of carbon contained in the reactive monomer.

### APPENDIX 5

The substrate processing method of any one of appendices 1 to 4, wherein the first monomer is an isocyanate,
the second monomer is a polyamine, and
the polymer material is a polyurea.

### APPENDIX 6

The substrate processing method of any one of appendices 1 to 5, wherein said (b) includes supplying a mixed gas of the processing gas and a rare gas.

### APPENDIX 7

The substrate processing method of any one of appendices 1 to 6, wherein said (b) includes controlling the substrate to be heated to 400° C. or less.

### APPENDIX 8

The substrate processing method of any one of appendices 1 to 7, wherein in said (a), the substrate having the recess in which the polymer material is embedded and a sealing film that covers the recess is provided, and
in said (b), the substrate is heated to decompose the polymer material, and the polymer material in the recess is removed through the sealing film.

### APPENDIX 9

A substrate processing apparatus comprising:
a processing chamber; and
a controller,
wherein the controller controls processes including:
(a) providing a substrate having a recess in which a polymer material having a urea bond is embedded by a vapor deposition polymerization reaction of a first monomer and a second monomer; and
(b) heating the substrate to a temperature at which the polymer material is thermally decomposed to decompose the polymer material by depolymerization,
wherein said (b) includes supplying a processing gas containing hydrogen, oxygen, or a halogen-based gas to decompose and gasify the reactive monomer generated by the depolymerization by active species contained in the plasma of the processing gas.

### APPENDIX 10

The substrate processing apparatus of appendix 9, wherein the substrate processing apparatus is a capacitively coupled plasma processing apparatus.

1. A substrate processing method comprising:
(a) providing a substrate having a recess in which a polymer material having a urea bond is embedded by a vapor deposition polymerization reaction of a first monomer and a second monomer; and
(b) heating the substrate to a temperature at which the polymer material is thermally decomposed to decompose the polymer material by depolymerization,
wherein said (b) includes supplying a processing gas containing hydrogen, oxygen, or a halogen-based gas to decompose and gasify the reactive monomer generated by the depolymerization by active species contained in the plasma of the processing gas.

2. The substrate processing method of claim 1, wherein said (b) includes controlling the flow rate of the processing gas such that the active species are consumed in the decomposition and gasification of the reactive monomer without reaching the substrate.

3. The substrate processing method of claim 2, wherein in said (b), the flow rate of the processing gas is controlled to less than 100 times the amount of carbon contained in the reactive monomer.

4. The substrate processing method of claim 3, wherein in said (b), the flow rate of the processing gas is controlled to less than 10 times the amount of carbon contained in the reactive monomer.

5. The substrate processing method of claim 1, wherein the first monomer is an isocyanate,
the second monomer is a polyamine, and
the polymer material is a polyurea.

6. The substrate processing method of claim 2, wherein the first monomer is an isocyanate,
the second monomer is a polyamine, and
the polymer material is a polyurea.

7. The substrate processing method of claim 1, wherein said (b) includes supplying a mixed gas of the processing gas and a rare gas.

8. The substrate processing method of claim 2, wherein said (b) includes supplying a mixed gas of the processing gas and a rare gas.

9. The substrate processing method of claim 1, wherein said (b) includes controlling the substrate to be heated to 400° C. or less.

10. The substrate processing method of claim 2, wherein said (b) includes controlling the substrate to be heated to 400° C. or less.

11. The substrate processing method of claim 1, wherein in said (a), the substrate having the recess in which the polymer material is embedded and a sealing film that covers the recess is provided, and
in said (b), the substrate is heated to decompose the polymer material, and the polymer material in the recess is removed through the sealing film.

12. The substrate processing method of claim 2, wherein in said (a), the substrate having the recess in which the polymer material is embedded and a sealing film that covers the recess is provided, and
in said (b), the substrate is heated to decompose the polymer material, and the polymer material in the recess is removed through the sealing film.

13. A substrate processing apparatus comprising:
a processing chamber; and
a controller,
wherein the controller controls processes including:
(a) providing a substrate having a recess in which a polymer material having a urea bond is embedded by a vapor deposition polymerization reaction of a first monomer and a second monomer; and
(b) heating the substrate to a temperature at which the polymer material is thermally decomposed to decompose the polymer material by depolymerization,
wherein said (b) includes supplying a processing gas containing hydrogen, oxygen, or a halogen-based gas to decompose and gasify the reactive monomer generated by the depolymerization by active species contained in the plasma of the processing gas.

14. The substrate processing apparatus of claim 13, wherein the substrate processing apparatus is a capacitively coupled plasma processing apparatus.
